(19) United States
(12) Patent Application Publication
(10) Pub. No.: US 2013/0104964 A1
(43) Pub. Date: May 2, 2013

(54) SOLAR CELL AND SOLAR CELL MODULE AND METHODS FOR MANUFACTURING THE SAMES

(71) Applicant: JYI-TSONG LIN, KAOHSIUNG (TW)

(72) Inventor: JYI-TSONG LIN, KAOHSIUNG (TW)

(21) Appl. No.: 13/659,593

(22) Filed: Oct. 24, 2012

Related U.S. Application Data
(60) Provisional application No. 61/551,560, filed on Oct. 26, 2011.

(51) Int. Cl. H01L 31/0224; H01L 31/18

(52) U.S. Cl. CPC H01L 31/022425; H01L 31/18
USPC 136/246; 136/256; 136/251; 438/98

(57) ABSTRACT

The present invention provides a solar cell including: at least one rear electrode, at least one solar main body layer, and at least one upper electrode. The at least one solar main body layer surrounds the at least one rear electrode. The at least one upper electrode surrounds the at least one solar main body layer. Furthermore, the present invention provides a method for manufacturing the solar cell. The method includes the following steps: forming at least one rear electrode base (substrate); forming at least one solar main body layer surrounding the at least one rear electrode base (substrate); and forming at least one upper electrode surrounding the at least one solar main body layer.

### CROSS-REFERENCE TO RELATED APPLICATIONS

This application claims the benefit of U.S. Provisional Patent Application No. 61/551,560 filed Oct. 26, 2011.

### BACKGROUND OF THE INVENTION

1. Field of the Invention

The present invention relates to a solar cell and solar cell module and method for manufacturing the solar cell.

2. Description of the Related Art

FIG. 1 is a schematic view of a conventional solar cell. Referring to FIG. 1, the conventional solar cell 10 includes a substrate 11, a rear electrode 12, a solar main body layer 13 and an upper electrode 14. The rear electrode 12 is formed on the substrate 11. The solar main body layer 13 is formed on the rear electrode 12. The upper electrode 14 is formed on the solar main body layer 13.

The solar main body layer 13 includes a P-type layer 131, a middle I layer 132 and an N-type layer 133. In another conventional solar cell 10, the solar main body layer 13 can only include a P-type layer 131 and an N-type layer 133. The substrate 11 of the conventional solar cell 10 is an expensive poly-silicon wafer substrate or other substrate, and covers a quite large plane area. Moreover, sunlight can only irradiate the upper electrode 14 from an upper side, resulting in low power and conversion efficiency.

### SUMMARY OF THE INVENTION

The present invention provides a solar cell. The solar cell includes at least one rear electrode, at least one solar main body layer, and at least one upper electrode. The at least one solar main body layer surrounds the at least one rear electrode. The at least one upper electrode surrounds the at least one solar main body layer.

The present invention provides a solar cell module including: at least one solar cell and a container. The container is used for receiving the least one solar cell.

The present invention provides a method for manufacturing solar cell comprising the following steps: forming at least one rear electrode; forming at least one solar main body layer surrounding the at least one rear electrode; and forming at least one upper electrode surrounding the at least one solar main body layer.

### BRIEF DESCRIPTION OF THE DRAWINGS

FIG. 1 shows a schematic view of a conventional solar cell;

FIG. 2 shows a schematic view of a solar cell according to a first embodiment of the present invention;

FIG. 3 shows a schematic view of a solar cell according to a second embodiment of the present invention;

FIG. 4 shows a schematic view of a solar cell according to a third embodiment of the present invention;

FIG. 5 shows a schematic view of a solar cell according to a fourth embodiment of the present invention;

FIG. 6 shows a schematic view of a rear electrode base according to an embodiment of the present invention;

FIG. 7 shows a schematic view of a solar cell module according to a fifth embodiment of the present invention;

FIG. 8 shows a schematic view of a solar cell module according to a sixth embodiment of the present invention;

FIG. 9 shows a schematic view of a solar cell module according to a seventh embodiment of the present invention;

FIG. 10 shows a schematic view of a solar cell module according to an eighth embodiment of the present invention;

FIG. 11 shows a schematic view of a solar cell module according to a ninth embodiment of the present invention; and

FIG. 12 shows a schematic view of a solar cell module according to a tenth embodiment of the present invention.

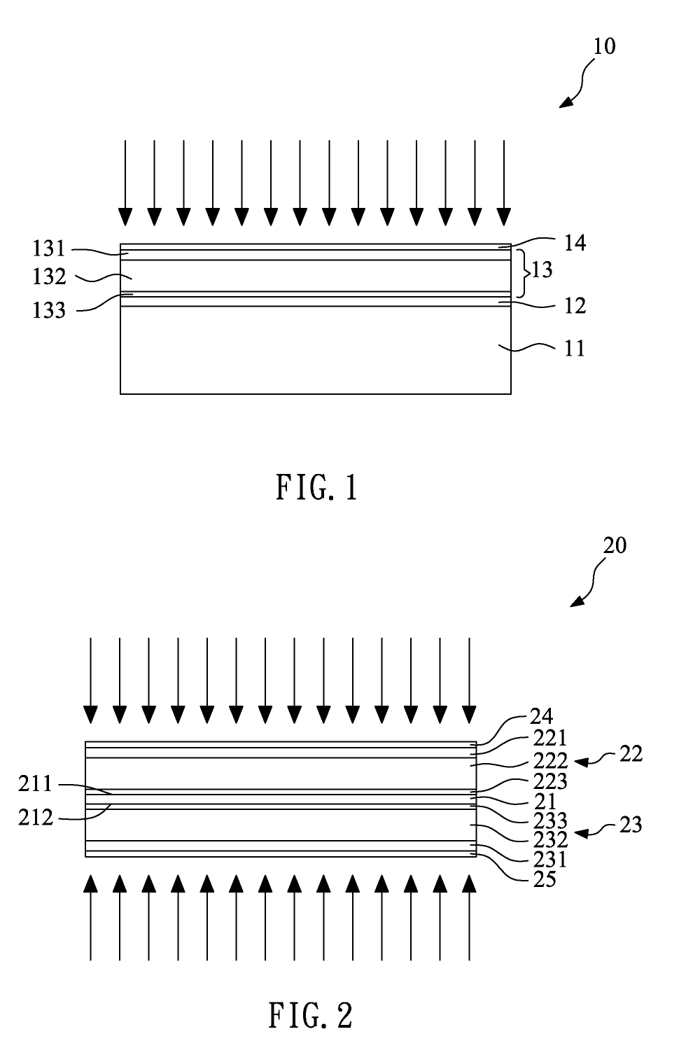

### DETAILED DESCRIPTION OF THE INVENTION

FIG. 2 shows a schematic view of a solar cell according to a first embodiment of the present invention. Referring to FIG. 2, according to the embodiment of the present invention the solar cell 20 includes a rear electrode 21, two solar main body layers 22 and 23, and two upper electrodes 24 and 25. The rear electrode 21 has a first surface 211 and a second surface 212, and the second surface 212 is opposite to the first surface 211.

The two solar main body layers 22 and 23 include a first solar main body layer 22 and a second solar main body layer 23. The first solar main body layer 22 is formed on the first surface 211 of the rear electrode 21, and the second solar main body layer 23 is formed on the second surface 212 of the rear electrode 21. That is, the two solar main body layers 22 and 23 surround part of the rear electrode 21. The first solar main body layer 22 includes a P-type layer 221, a middle I layer 222 and an N-type layer 223, and the second solar main body layer 23 includes a P-type layer 231, a middle I layer 232 and an N-type layer 233. In other embodiments, the first solar main body layer or the second solar main body layer can only include a P-type layer and an N-type layer.

The two upper electrodes 24 and 25 include a first upper electrode 24 and a second upper electrode 25. The first upper electrode 24 is formed on the first solar main body layer 22, and the second upper electrode 25 is formed on the second solar main body layer 23. That is, the two upper electrodes 24 and 25 surround part of the two solar main body layers 22 and 23.

In this embodiment, each of the two opposite surfaces of the rear electrode 21 has a solar main body layer, and each solar main body layer has an upper electrode. The rear electrode 21 can be a transparent conductive material. Therefore, the two surfaces can receive sunlight, increasing power and conversion efficiency.

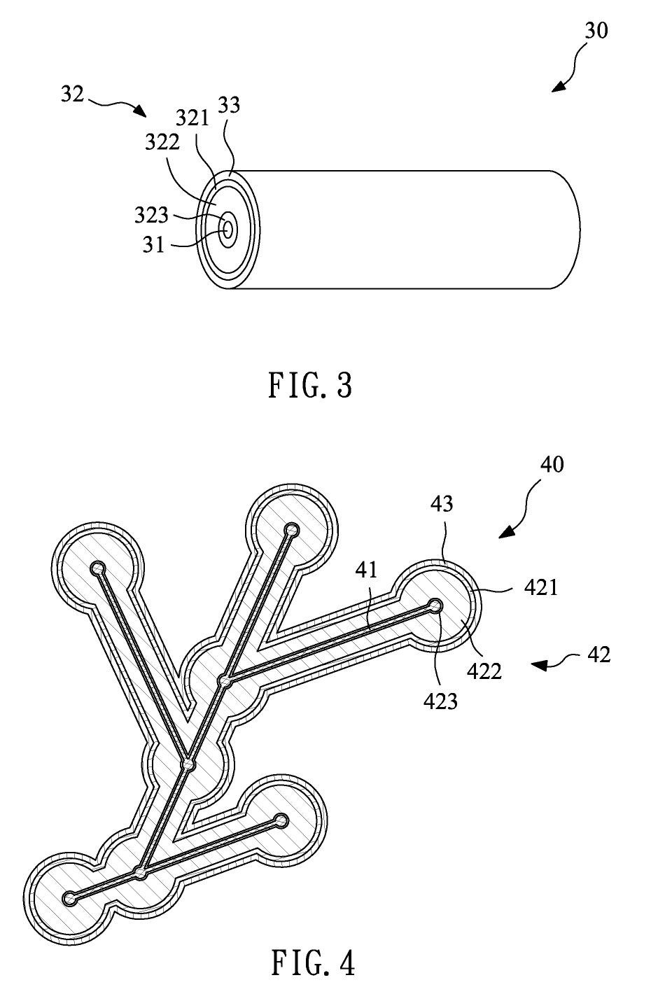

Referring to FIG. 3, it shows a schematic view of a solar cell according to a second embodiment of the present invention. The solar cell 30 includes a rear electrode 31, a solar main body layer 32, and an upper electrode 33. The rear electrode 31 is cylindrical.

The solar main body layer 32 surrounds the rear electrode 31, and the solar main body layer 32 includes a P-type layer 321, a middle I layer 322 and an N-type layer 323. In other embodiments, the solar main body layer can only include a P-type layer and an N-type layer. The upper electrode 33 surrounds the solar main body layer 32. That is to say, the upper electrode 33 and the solar main body layer 32 form a cylindrical tube. In other embodiments, the upper electrode and the solar main body layer can surround a triangular rear electrode, a plate rear electrode, or other shapes of rear electrodes, so as to form a triangular tube, a plate tube or other shapes of tubes.

In this embodiment, the upper electrode 33 and the solar main body 32 surround the rear electrode 31, so the upper electrode can receive sunlight from all sides (for example, 360 degrees), significantly increasing the power and the conversion efficiency.

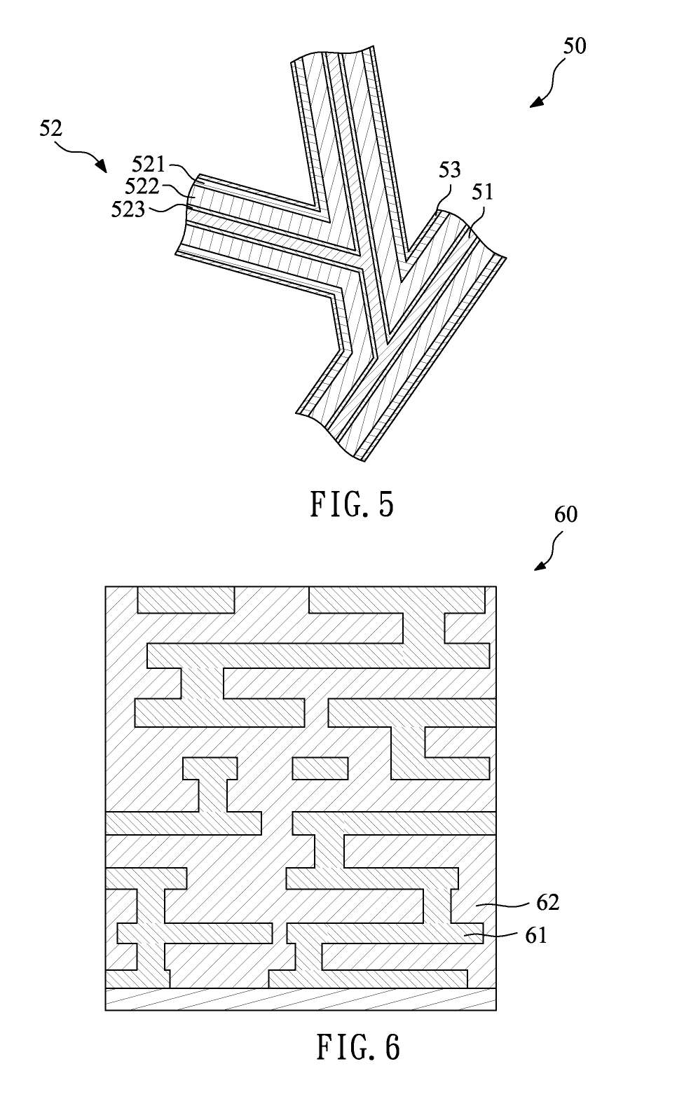

Referring to FIG. 4, it shows a schematic view of a solar cell according to a third embodiment of the present invention. The solar cell 40 includes a rear electrode 41, a solar main body layer 42, and an upper electrode 43. Referring to FIG. 5, it shows a schematic view of a solar cell according to a fourth embodiment of the present invention. The solar cell 50 includes a rear electrode 51, a solar main body layer 52, and an upper electrode 53. The method for manufacturing the solar cell according to the present invention is described as follows with reference to FIG. 4 and FIG. 5.

The rear electrodes 41 and 51 can have a one-dimensional line structure or pipeline structure, a two-dimensional plane structure, curved surface structure, or plane and curved pipeline structure, or a three-dimensional dendritic structure or dendritic pipeline structure. The rear electrodes 41 and 51 can have a plane or curved steel plate or pipeline structure, or a drawer steel plate or pipeline structure. The rear electrodes 41 and 51 can be circular nest-shaped, quadrangular nest-shaped, triangular nest-shaped, or hexagonal nest-shaped. The rear electrodes 41 and 51 can also have an irregular cerebrovascular structure, an irregular chlorophyll nest structure, or any other connection structure having interspaces in the nature.

The periphery (namely the outline) of the rear electrodes 41 and 51 can be any shape in the nature, for example, the outline can be like tofu, a bottle, a ball, a regular icosahedron, a football, or a flower with four petals.

The rear electrode can be of Transparent Conducting Oxide (TCO) materials, transparent thin metal materials, or thin grapheme and graphite materials. Materials with high conductivity, low resistance, and extremely high thermal conductivity are preferable.

The rear electrode can be manufactured through the following methods.

1. The rear electrode can be manufactured through industrial molding. In this method, a three-dimensional model structure of the rear electrode shown in FIG. 4 or FIG. 5 is designed, and the rear electrode is directly obtained through molding. A large quantity of rear electrodes can be provided. The three-dimensional model structure can be the rear electrode of the solar cell. The rear electrode with the three-dimensional model structure of the present invention can be used as a substrate (or base), so that the expensive wafer substrate of the conventional solar cell is no longer required.

2. The rear electrode can be manufactured through Integrated Circuit (IC) planar process. Referring to FIG. 6, a mask is first designed for the process according to the conventional IC Lithography technique. Connection VIAs and contact windows are outlined on the mask. A buffer layer that can be peeled is then coated on the wafer substrate or other substrates during the process. A conductive layer 61 and an insulation layer 62 are then coated. After that, the contact windows and the VIAs are opened on the insulation layer using the mask, and a conductive layer is then coated thereon. The preceding steps are repeated. In this way, a three-dimensional steel plate-shaped, nest-shaped, or hollow drawer-shaped structure 61 with multiple layers connected to each other is formed. After isotropic etching on the insulation body 62 and the peeling process, the rear electrode base 60 is obtained, namely, the rear electrode substrate (or the base) of the solar cell is manufactured, which is different from conventional substrates. It should be noted that the peeling process can also be omitted. The solar cell and the circuit can be integrated on the wafer substrate, so as to obtain a system that does not need an additional power supply. Such system is referred to as SUN ON CHIP system, that is, the solar cell is manufactured inside the System On Chip (SOC). It also should be noted that, in the SUN ON CHIP system according to the present invention, when the solar cell part is manufactured, in order to prevent the IC from being polluted by the subsequent process of manufacturing the solar cell, one or more suitable passivation layers can be manufactured for the IC part, so as to protect the internal circuit from being eroded, etched, affected or polluted by the solar cell process.

3. An insulation base is directly industrial molded, and a conductive layer is further manufactured on the insulation base. In this manner, a tubular rear electrode base the same as that in the first method is obtained.

The solar main body layers 42 and 52 wrap the rear electrodes 41 and 51. The solar main body layer can be formed by PN or PIN, or P⁺PN or P⁺PIN, or PNN⁺or PINN⁺, or P⁺PN N⁺or P⁺PINN⁺ with one or more conjunctions. Transparent buffer layers are formed together with multiple conjunctions. Through adding the N⁺ layer and the P⁺ layer to the solar main body layer, trap and recombination centers are reduced in an area near the upper electrode, thereby increasing the solar energy conversion efficiency. In another aspect, main carrier recombination in the recombination center can be enhanced, generating light that can be reused. Such light can be recycled, thereby improving the conversion efficiency. It should be noted that, in the solar cell or module of the present invention, light can be recycled. It is worthwhile noting that the solar main body layer can be formed by any kinds of conventional solar cell body, such as III-V solar cell, CIGS solar cell, or Dye-Sensitized Solar Cell.

The solar main body layer can be manufactured through the following method.

1. The preceding rear electrode base is used as a substrate, and is fixed in the process cavity (two ends of the base are hanging in the cavity) or hanging in the process cavity. Materials of the solar main body layer are manufactured on the rear electrode base using the methods for manufacturing the solar cell. (Conventional poly-silicon or other kinds of substrates are not required, which significantly reduces the cost.)

2. Chemical Vapor Deposition (CVD), Physical Vapor Deposition (PVD) sputtering, Chemical Bath Deposition (CBD), Sol-Gel, solution liquid deposition, crystal growth, spray, paste and electroplating methods can be used to manufacture each layer of material in the solar main body layer.

3. The rear electrode base is submerged into a plating solution or a material solution to obtain each layer of uniform material in the solar main body layer.

4. To obtain each layer of uniform material in the solar main body layer, if the CVD method is used, an ambient condition with the low temperature, low pressure, low rate, and inert gas is preferred.

The upper electrodes 43 and 53 wrap the solar main body layers 42 and 52. In the present invention, the solar cell can be an open solar cell or a closed solar cell. Light can randomly enter and exit the open solar cell; while light can only enter the closed solar cell, and the closed solar cell cannot emit reflected light, that is, the incident light does not exit the closed solar cell in an ideal sense.

In the open solar cell, a transparent conductive layer is manufactured and used as the upper electrode after the solar main body layer is manufactured.

In the closed solar cell, an anti-reflection transparent conductive layer is manufactured and used as the upper electrode, or an anti-reflection layer and a transparent conductive layer are manufactured and used as the upper electrode after the solar main body layer is manufactured. Through the anti-reflection layer, incident light cannot exit the solar cell.

The solar cell module of the present invention usually includes a container. One or more solar cells of the present invention are connected in series or in parallel, and disposed in the container to form the solar cell module of the invention. The container can be a container-shaped open or closed cell of the present invention. The container can be of other transparent materials such as glass or acryl. The container can also be an integrated container or a container inlaid with one or more condensing modules. An anti-reflection layer or a total reflection layer made of materials capable of performing total reflection, such as mercury or metal, can or can not be manufactured or evaporated in the container, so that light incident from a side surface or an upper surface of the container does not exit the container after being reflected, instead, the light is reflected back and forth or resonated inside the container, and is absorbed by the solar cell of the present invention disposed therein, increasing the photoelectric conversion efficiency. If formed by the solar cell of the present invention, the container can be connected in series or in parallel with the solar cells disposed therein, further improving the module performance.

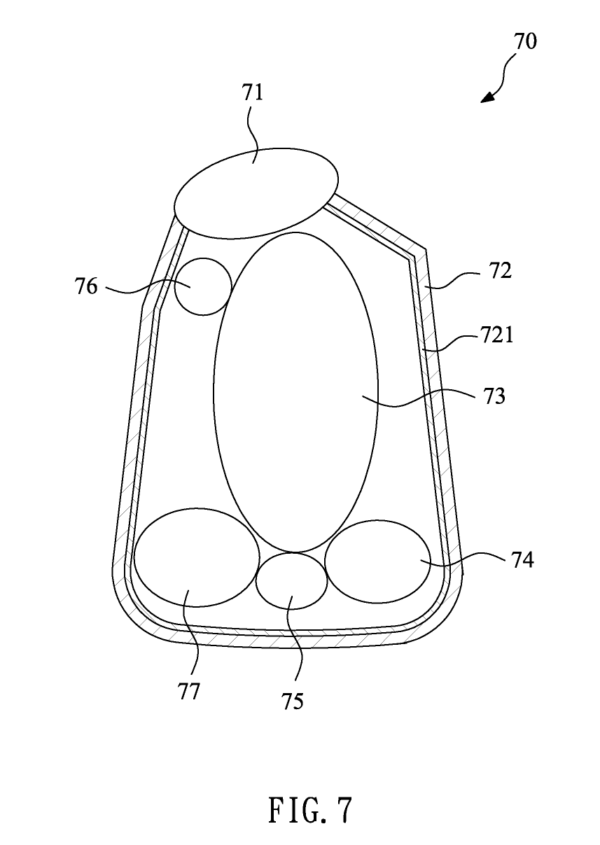

Referring to FIG. 7, it shows a schematic view of a solar cell module according to a fifth embodiment of the present invention. The solar cell module 70 includes at least one condensing module 71, a container 72, and solar cells 73, 74, 75, and 76. The solar cells 73, 74, 75, and 76 can be the preceding solar cells 20, 30, 40, and 50 of the present invention, or can be open solar cells or closed solar cells, which are not described in detail herein again. In other embodiments, the solar cell module 70 does not include the condensing module 71.

The condensing module 71 receives sunlight. Preferably, the condensing module 71 can be a convex lens module, which is a set of convex lenses that can condense light at the solar cell. The condensing module 71 can be disposed on the container 72, or can be a part of the container 72.

The container 72 is used to receive the solar cells 73, 74, 75, and 76. Preferably, the container 72 is made of transparent glass, or formed by the open solar cell or closed solar cell of the present invention, or made of other transparent materials (the light transmittance is preferably close to 100). In this embodiment, the container 72 can further include an anti-reflection layer or a total reflection layer 721 made of materials capable of performing total reflection, such as mercury or metal, so that light incident from a side surface or upper surface of the container 72 does not exit the container 72 after being reflected. That is to say, all of the light is received and used by the solar cells 73, 74, 75, and 76 in the container 72.

The solar cells 73, 74, 75, and 76 can be connected in series or in parallel using two electrodes thereof, forming high-power solar cell module to be used by large-scale or high-power devices and systems. The solar cell module 70 of the present invention further includes a storage cell 77, connected to the solar cells 73, 74, 75, and 76, so as to store electric energy generated by the solar cells 73, 74, 75, and 76. In this embodiment, the storage cell 77 is disposed in the container 72. In other embodiments, the storage cell can be disposed outside the container. In this manner, in daytime, the solar cell module can supply power, and the remaining electric energy is stored in the storage cell. At night, the electric energy stored in the storage cell can be used, so as to achieve an effect of continuously supplying power.

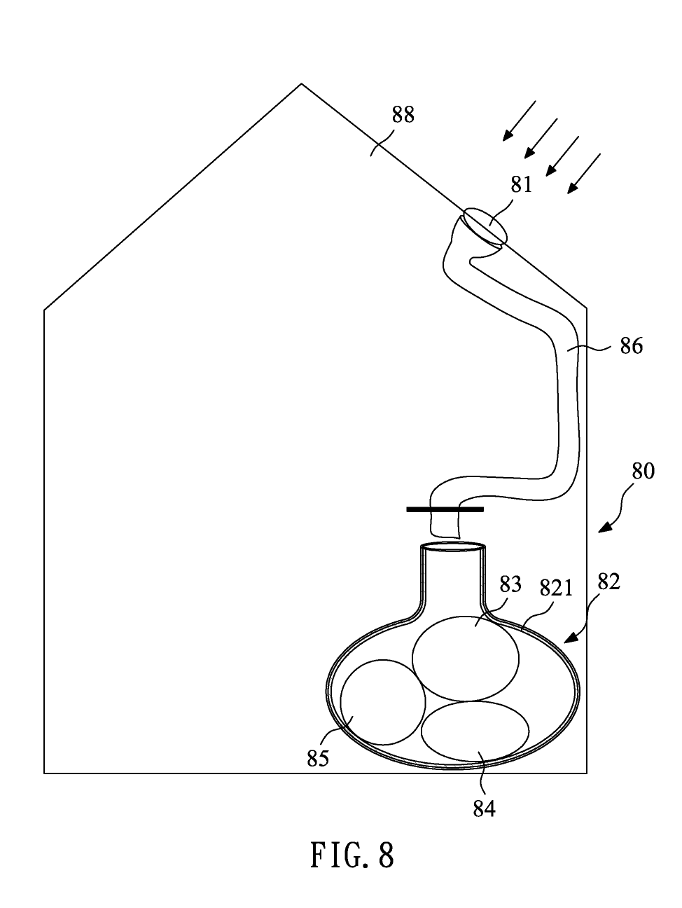

Referring to FIG. 8, it shows a schematic view of a solar cell module according to a sixth embodiment of the present invention. The solar cell module 80 includes at least one condensing module 81, a container 82, solar cells 83 and 84, a storage cell 85, and a fiber module 86. In other embodiments, the solar cell module 80 does not include the condensing module 81.

Compared with the solar cell module 70, the solar cell module 80 further includes the fiber module 86. Moreover, the container 82, the solar cells 83 and 84, the storage cell 85 and the fiber module 86 of the solar cell module 80 can be disposed in a building or house 88.

The condensing module 81 of the solar cell module 80 is disposed at any outdoor place where sunlight or light exists, so as to receive a light source. One end of the fiber module 86 is connected to the condensing module 81, and the other end of the fiber module 86 is connected into the container 82 or to the solar cells 83 and 84. Through the fiber module 86, light is introduced into the indoor solar cells 83 and 84 like a wire, and is used to generate electric energy that is used by household appliances or stored in the storage cell 85.

The solar cell module 80 according to the embodiment of the present invention is not necessarily disposed outside the building or the house to receive sunlight, and is not limited by the space outside the building or the house, which greatly improves the disposition flexibility.

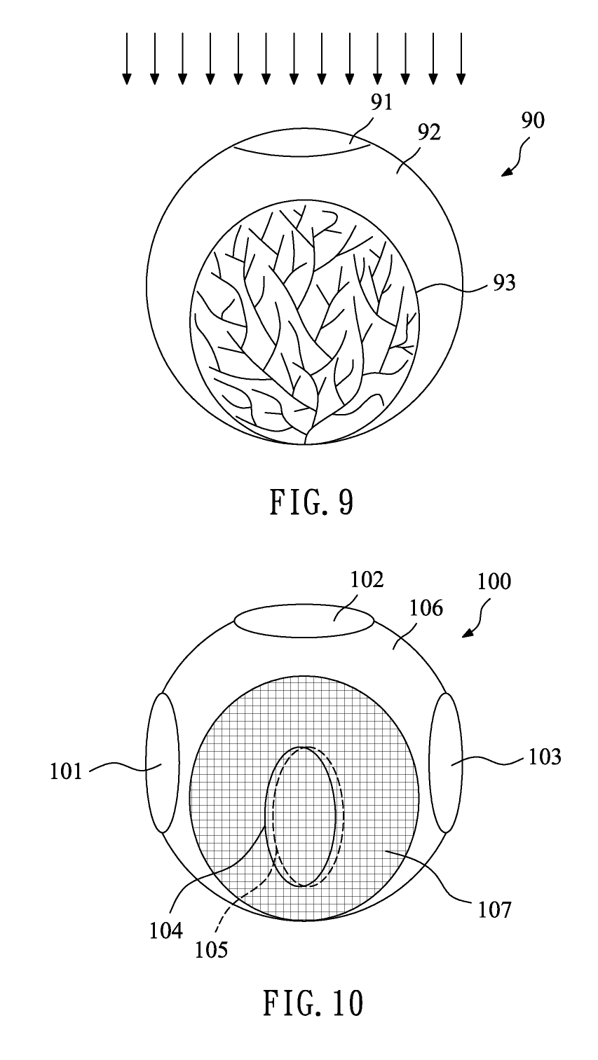

Referring to FIG. 9, it shows a schematic view of a solar cell module according to a seventh embodiment of the present invention. The solar cell module 90 includes a condensing module 91, a container 92 and a solar cell 93. The container 92 can be, but is not limited to a circular container. The condensing module 91 is disposed in the container 92, or is integrated with the container 92. The solar cell 93 can be, but is not limited to a circular solar cell. A rear electrode therein can be manufactured according to the preceding method for manufacturing the solar cell of the present invention.

Referring to FIG. 10, it shows a schematic view of a solar cell module according to an eighth embodiment of the present invention. The solar cell module 100 includes five (but is not limited to five) condensing modules 101, 102, 103, 104, and 105, a container 106, and a solar cell 107. The five condensing modules 101, 102, 103, 104, and 105 are disposed in the container 106 to receive light from multiple directions, so as to increase efficiency.

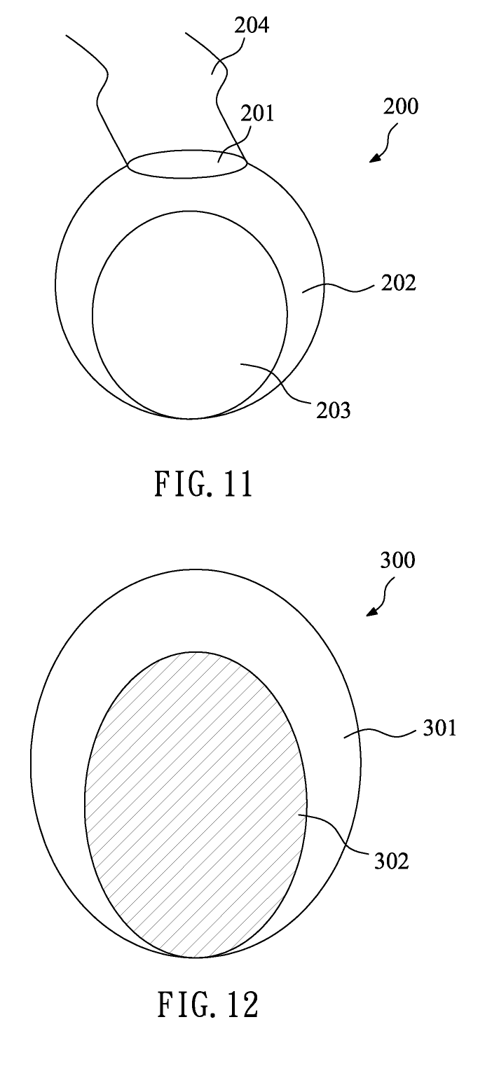

Referring to FIG. 11, it shows a schematic view of a solar cell module according to a ninth embodiment of the present invention. The solar cell module 200 includes a condensing module 201, a container 202, a solar cell 203, and an external apparatus 204. The external apparatus 204 can introduce external light into the solar cell module 200, so that the external light can be used by the solar cell 203.

Referring to FIG. 12, it shows a schematic view of a solar cell module according to a tenth embodiment of the present invention. The solar cell module 300 includes a container 301 and a solar cell 302. The container 301 can be, but is not limited to an elliptic container. The solar cell 302 can be, but is not limited to an elliptic solar cell. The solar cell 302 can be smaller than the inner part of the container 301, or fills the entire inner part of the container 301.

The solar cell modules according to the embodiment of the present invention can be attached to a support with a rotary device, so as to form a rotary solar cell module, thereby facilitating absorption of light with different frequencies and heat dissipation, and improving the conversion efficiency.

The solar cell modules according to the embodiment of the present invention can be manufactured into or assembled into leafs or branches of wind power generating equipment. Alternatively, the solar cell modules according to the embodiment of the present invention can form the entire wind power generating equipment, so that the wind and sunlight are used to generate power at the same time. Such equipment can be used on transportation means such as vehicles, airplanes, and ships, and in a windy environment or device.

The solar cell modules according to the embodiment of the present invention can be manufactured into or assembled into leafs or branches of hydroelectric power generating equipment. Alternatively, the solar cell modules according to the embodiment of the present invention can form the entire hydroelectric power generating equipment, so that the water and sunlight are used to generate power at the same time. The hydroelectric power generating equipment formed by the solar cell modules according to the embodiment of the present invention can be disposed in an environment with water, for example, in an ocean, a brook, or a waterfall.

The solar cell modules according to the embodiment of the present invention can be manufactured into or assembled into various materials used in buildings, such as tiles, ceramic tiles, windows, and various decorations. Alternatively, the solar cell modules according to the embodiment of the present invention can form the entire building. The solar cell modules according to the embodiment of the present invention are capable of implementing Building Integrated Photovoltaics (BIPV). By an extension of this logic, space shuttles, space ships, airplanes, and space stations can be manufactured by the solar cell modules according to the embodiment of the present invention and the BIPV, making the earth and universe cleaner.

Referring to FIG. 2, FIG. 3, FIG. 4 or FIG. 5, the solar cell 20 in FIG. 2 is used as an example for description. The rear electrode 21 of the solar cell 20, the solar cell main body layers 22 and 23, the upper electrodes 24 and 25, or each single layer can be made of isotopes respectively or at the same time. The doped impurities are replaced by isotopes respectively or at the same time. The layers or the solar cell module is properly radiated by neutrons respectively or at the same time, so that materials of the radiated part become isotopes. In this manner, phonons or other unknown microparticles are generated in the solar cell and the solar cell module. The number of neutrons in the nucleus changes in each layer of material, the nucleus diameter changes, and the external electron cloud distribution and the atom diameter also change, thereby promoting interaction and resonance among electrons, phonons, photons, and microparticles. Therefore, the absorption efficiency of the photons is increased, and furthermore, the entire photoelectric conversion efficiency of the entire solar cell and solar cell module is improved.

While several embodiments of the present invention have been illustrated and described, various modifications and improvements can be made by those skilled in the art. The embodiments of the present invention are therefore described in an illustrative but not in a restrictive sense. It is intended that the present invention should not be limited to the particular forms as illustrated and that all modifications which maintain the spirit and scope of the present invention are within the scope defined in the appended claims.

What is claimed is:

1. A solar cell comprising:
at least one rear electrode;
at least one solar main body layer, surrounding the at least one rear electrode; and
at least one upper electrode, surrounding the at least one solar main body layer.

2. The solar cell according to claim 1, wherein the rear electrode has a first surface and a second surface, and the second surface is opposite to the first surface; the two solar main body layers comprise a first solar main body layer and a second solar main body layer, the first solar main body layer is formed on the first surface of the rear electrode, and the second solar main body layer is formed on the second surface of the rear electrode; the two upper electrodes comprise a first upper electrode and a second upper electrode, the first upper electrode is formed on the first solar main body layer, and the second upper electrode is formed on the second solar main body layer.

3. The solar cell according to claim 1, wherein the rear electrode is a cylindrical rear electrode, a triangular rear electrode or a plate rear electrode; the solar main body layer surrounds the rear electrode to form a cylindrical, triangular or a plate tube; the upper electrode surrounds the solar main body layer to form a cylindrical, triangular or a plate tube

4. The solar cell according to claim 1, wherein the rear electrode is a one-dimensional line structure or pipeline structure, a two-dimensional plane structure, curved surface structure, or plane and curved pipeline structure, or a three-dimensional dendritic structure or dendritic pipeline structure.

5. The solar cell according to claim 1, wherein the rear electrode is a plane or curved steel plate or pipeline structure, or a drawer steel plate or pipeline structure; or is circular nest-shaped, quadrangular nest-shaped, triangular nest-shaped, or hexagonal nest-shaped.

6. The solar cell according to claim 1, wherein the rear electrode is an irregular cerebrovascular structure, an irregular chlorophyll nest structure, or connection structure having interspaces in the nature.

7. The solar cell according to claim 1, wherein the periphery of the rear electrode is the shape of tofu, a bottle, a ball, a regular icosahedron, a football, or a flower with four petals.

8. A solar cell module, comprising:
at one solar cell according to claim 1; and
a container, for receiving the least one solar cell.

9. The solar cell module according to claim 8, further comprising at least one condensing module for receiving sunlight, the at least one condensing module is disposed on the container, or is a part of the container.

10. The solar cell module according to claim 8, further comprising at least one fiber module for receiving sunlight, and transmitting sunlight to the at least one solar cell.

11. The solar cell module according to claim 8, further comprising at least one storage cell, connected to the at least one solar cell to store electric energy generated by the at least one solar cell.

12. The solar cell module according to claim 8, wherein the container further comprises at least one anti-reflection layer or total reflection layer.

13. A method for manufacturing the solar cell according to claim 1, comprising the following steps:
forming at least one rear electrode;
forming at least one solar main body layer surrounding the at least one rear electrode; and
forming at least one upper electrode surrounding the at least one solar main body layer.

14. The method according to claim 13, wherein the at least one rear electrode is formed through industrial molding.

15. The method according to claim 13, wherein the at least one rear electrode is formed through Integrated Circuit (IC) planar process, and comprises the following steps:
coating a buffer layer on a substrate;
coating a conductive layer and an insulation layer;
forming contact windows and VIAs on the insulation layer using a mask;
coating a conductive layer; and
repeating the above steps to form the at least one rear electrode.

16. The method according to claim 13, wherein the at least one rear electrode is formed through industrial molding an insulation base, then a conductive layer is formed on the insulation base.

17. The method according to claim 13, wherein the at least one solar main body layer is formed by fixing or hanging the at least one rear electrode in a process cavity, then materials of the solar main body layer are formed on the at least one rear electrode.

18. The method according to claim 13, wherein the at least one solar main body layer is formed by Chemical Vapor Deposition (CVD), Physical Vapor Deposition (PVD) sputtering, Chemical Bath Deposition (CBD), Sol-Gel, solution liquid deposition, crystal growth, spray, paste or electroplating method.

19. The method according to claim 13, wherein the at least one rear electrode is submerged into a plating solution or a material solution to form the at least one solar main body layer.

20. The method according to claim 13, wherein the at least one rear electrode, the at least one solar cell main body layer, the at least one upper electrode, or each single layer is made of isotopes respectively or at the same time, or the doped impurities are replaced by isotopes respectively or at the same time, or the layers or the solar cell is properly radiated by neutrons respectively or at the same time, so that materials of the radiated part of the layer or the solar cell become isotopes.
